(19) United States
(12) Patent Application Publication
(10) Pub. No.: US 2020/0111948 A1
(43) Pub. Date: Apr. 9, 2020

(54) PIEZOELECTRIC CERAMIC STACKED STRUCTURE AND PIEZOELECTRIC ACCELEROMETER

(71) Applicant: FATRI UNITED TESTING & CONTROL (QUANZHOU) TECHNOLOGIES CO., LTD., Fujian (CN)

(72) Inventors: Yongzhong NIE, Xiamen City, Fujian (CN); Zhihua FU, Xiamen City, Fujian (CN)

(73) Assignee: FATRI UNITED TESTING & CONTROL (QUANZHOU) TECHNOLOGIES CO., LTD., Fujian (CN)

(21) Appl. No.: 16/617,818

(22) PCT Filed: May 25, 2018
(86) PCT No.: PCT/CN2018/088457

§ 371 Date: Nov. 27, 2019

(30) Foreign Application Priority Data
Jun. 9, 2017 (CN) 201710434219.6

(51) Int. Cl. H01L 41/187; H01L 41/083

(52) U.S. Cl. CPC H01L 41/187; H01L 41/0835

(57) ABSTRACT

Disclosed is a piezoelectric ceramic stacked structure and a piezoelectric accelerometer. The piezoelectric ceramic stacked structure comprises: a columnar piezoelectric ceramic body comprising a first end portion and a second end portion opposite to each other in the axial direction, wherein the columnar piezoelectric ceramic body comprises two or more piezoelectric ceramic stacked layers, and two adjacent electrodes of two adjacent piezoelectric ceramic stacked layers have same polarity; a surface, facing the first end portion, of each piezoelectric ceramic stacked layer is provided with an electrode lead terminal; and two adjacent electrode lead terminals have opposite polarities and are staggered in the axial direction, and the electrode lead terminal provided on each piezoelectric ceramic stacked layer in the columnar piezoelectric ceramic body is exposed to an external environment; and a connecting component, wherein the two or more piezoelectric ceramic stacked layers are connected by the connecting component.

### CROSS-REFERENCE TO RELATED APPLICATION

This application is a National Stage of International Application No. PCT/CN2018/088457 filed on May 25, 2018, which claims priority to Chinese Patent Application No. 201710434219.6 filed on Jun. 9, 2017 and entitled “PIEZOELECTRIC CERAMIC STACKED STRUCTURE AND PIEZOELECTRIC ACCELEROMETER”, both of which are incorporated herein by reference in their entireties.

### TECHNICAL FIELD

The disclosure relates to the field of detection device, and in particular to a piezoelectric ceramic stacked structure and a piezoelectric accelerometer.

### BACKGROUND

The piezoelectric accelerometer is used more and more widely to measure the vibration of an object. The piezoelectric ceramic stacked structure currently used as the piezoelectric element is often provided with a connecting layer between piezoelectric ceramic sheets. Although the structure realizes the assembly of the piezoelectric element, the height of the piezoelectric ceramic stacked structure is increased due to the engagement between the connecting layer and the piezoelectric ceramic sheets. When applied in a vibrating environment, the above piezoelectric ceramic stacked structure may be deformed to absorb a part of the energy, thereby reducing the overall rigidity of the accelerometer and affecting the frequency response characteristics.

### SUMMARY

The embodiments of the disclosure provide a piezoelectric ceramic stacked structure and a piezoelectric accelerometer, which can improve the rigidity of the multilayer piezoelectric ceramic stacked structure so as to improve the frequency response characteristic and can also reduce the stress value fluctuations in a high temperature environment. Further, the structure is simple and is suitable for mass production.

One aspect of an embodiment of the disclosure provides a piezoelectric ceramic stacked structure including: a columnar piezoelectric ceramic body including a first end portion and a second end portion opposite to each other in the axial direction of the columnar piezoelectric ceramic body, wherein the columnar piezoelectric ceramic body includes two or more piezoelectric ceramic stacked layers, and two adjacent electrodes of two adjacent piezoelectric ceramic stacked layers among the two or more piezoelectric ceramic stacked layers have the same polarity; a surface, facing the first end portion, of each of the two or more piezoelectric ceramic stacked layer is provided with an electrode lead terminal; two adjacent electrode lead terminals among the two or more electrode lead terminals have opposite polarities and are arranged in a staggered manner in the axial direction, the electrode lead terminal provided on each of the two or more piezoelectric ceramic stacked layers in the columnar piezoelectric ceramic body is exposed to an external environment; and a connecting component, wherein the two or more piezoelectric ceramic stacked layers are connected by the connecting component.

The piezoelectric ceramic stacked structure according to the embodiment of the disclosure includes two or more piezoelectric ceramic stacked structures. Each of the two or more piezoelectric ceramic stacked layers is provided with one electrode lead terminal, and an external device can be directly and electrically connected with the electrode lead terminal, so that there is no need to separately provide electrode sheet between the two adjacent piezoelectric ceramic stacked layers. Therefore, the piezoelectric ceramic stacked structure is simple and compact, and the overall rigidity of the multilayer piezoelectric ceramic stacked structure is improved, and the frequency response characteristics is improved.

Another aspect of an embodiment of the disclosure provides a piezoelectric accelerometer including the piezoelectric ceramic stacked structure as described above.

### BRIEF DESCRIPTION OF THE DRAWINGS

Features, advantages, and technical effects of the exemplary embodiments of the disclosure will be described below with reference to the drawings.

FIG. 1 is a schematic view showing the overall structure of a piezoelectric ceramic stacked structure according to an embodiment of the disclosure.

FIG. 2 is a front perspective structural schematic view of the piezoelectric ceramic stacked structure according to an embodiment of the disclosure.

FIG. 3 is a schematic structural view of a columnar piezoelectric ceramic body according to an embodiment of the disclosure.

FIG. 4 is a schematic top structural view of a columnar piezoelectric ceramic body according to another embodiment of the disclosure.

FIG. 5 is a schematic structural view of a piezoelectric ceramic sheet according to an embodiment of the disclosure.

FIG. 6 is a schematic structural view of a piezoelectric ceramic sheet according to another embodiment of the disclosure.

In the drawings, the figures are not drawn to scale.

### DETAILED DESCRIPTION

Implementations of the disclosure will be further described in detail below in conjunction with the drawings and embodiments. The detailed description of the embodiments and the accompanying drawings are intended to illustrate the principle of the disclosure but are not intended to limit the scope of the disclosure, i.e., the disclosure is not limited to the described embodiments.

In the description of the disclosure, it should be noted that, unless otherwise stated, the meaning of “multiple” is two or more; the orientation or positional relationship indicated by the terms “upper”, “lower” “inside”, “outside” and like is merely for the convenience of the description of the disclosure and the simplification of the description, and does not indicate or intend that the involved device or element must have the specific orientation or must be configured or operated in a specific orientation, and therefore, should not to be construed as a limitation to the disclosure. Moreover, the terms “first”, “second”, “third”, and the like are only used for the purpose of description, and should not to be construed as indicating or implying relative importance. The orientation words appearing in the following description refer to the directions shown in the drawings, and are not intended to limit the specific structure of the specific structure of the disclosure. In the description of the disclosure, it should be noted that, unless otherwise stated and defined, the terms “mount”, “connect with”, and “connect to” are to be understood broadly. The specific meaning of the above terms in the disclosure may be understood by the skilled in the art based on the specific situation.

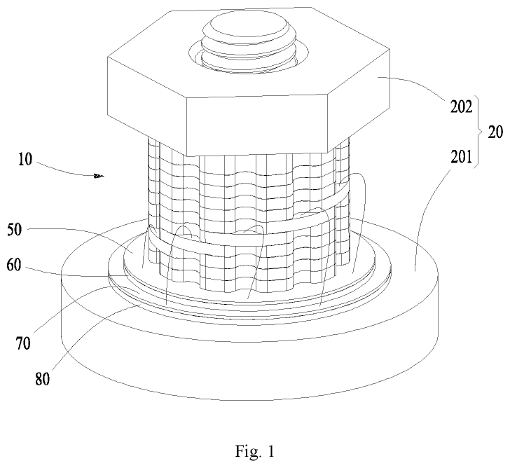

For a better understanding of the disclosure, a piezoelectric ceramic stacked structure according to the embodiments of the disclosure will be described in detail below with reference to FIGS. 1 to 6.

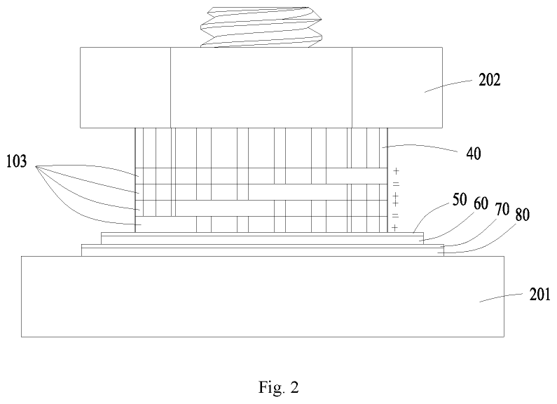

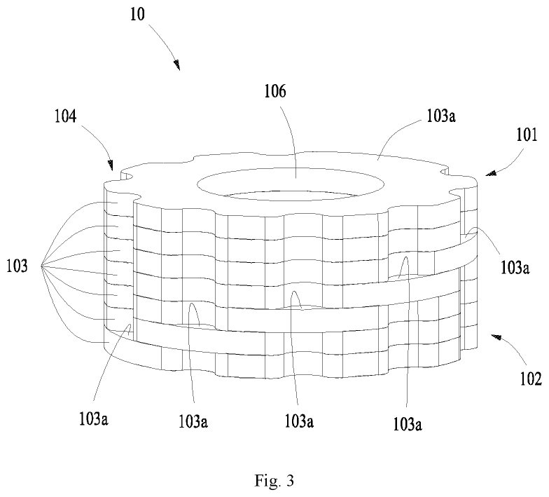

As shown in FIG. 1, an embodiment of the disclosure relates to a piezoelectric ceramic stacked structure, including a columnar piezoelectric ceramic body 10 and a connecting component 20 connected to the columnar piezoelectric ceramic body 10. Referring to FIG. 3, the columnar piezoelectric ceramic body 10 includes a first end portion 101 and a second end portion 102 which are opposite to each other in the axial direction thereof. The first end portion 101 and the second end portion 102 here are merely for the purpose of describing the technical solution according to the embodiment of the disclosure, and do not limit the technical solution according to the embodiment of the disclosure. The columnar piezoelectric ceramic body 10 includes two or more piezoelectric ceramic stacked layers 103. Each of the two or more piezoelectric ceramic stacked layers 103 in the present embodiment has a columnar structure. Two adjacent electrodes of the two adjacent piezoelectric ceramic stacked layers 103 among the two or more piezoelectric ceramic stacked layers 103 have the same polarity. As shown in FIG. 2, each of the two or more piezoelectric ceramic stacked layers 103 includes a positive electrode and a negative electrode. From the first end portion 101 to the second end portion 102, of the two adjacent piezoelectric ceramic stacked layers 103, the positive electrode (or negative electrode) of one piezoelectric ceramic stacked layer 103 and the positive electrodes (or the negative electrode) of the other piezoelectric ceramic stacked layer 103 are electrically connected with each other such that two adjacent piezoelectric ceramic stacked layers 103 are sequentially stacked in parallel.

As shown in FIG. 3, a surface, facing the first end portion 101, of each piezoelectric ceramic stacked layer 103 according to the present embodiment of the disclosure is provided with an electrode lead terminal 103a. The piezoelectric ceramic stacked layer 103 is electrically connected to an external device through the electrode lead terminal 103a. In one embodiment, the electrode lead terminal 103a may be a part of the surface of the piezoelectric ceramic stacked layer 103. That is, the electrode lead terminal 103a is not a structural member that is separately added, thereby reducing the process of separately manufacturing the electrode lead terminal 103a on the piezoelectric ceramic stacked layer 103. For each of the two or more piezoelectric ceramic stacked layers 103, the electrode lead terminal 103a in the present embodiment may be a positive electrode of the piezoelectric ceramic stacked layer 103 or a negative electrode of the piezoelectric ceramic stacked layer 103. The piezoelectric ceramic stacked layers 103 included in the columnar piezoelectric ceramic body 10 have the same number as electrode lead terminals 103a. Two adjacent electrode lead terminals 103a among the two or more electrode lead terminals 103a have opposite polarities. From the first end portion 101 to the second end portion 102, of the two adjacent piezoelectric ceramic stacked layers 103, the electrode lead terminal 103a of one piezoelectric ceramic stacked layer 103 is a positive electrode (or a negative electrode), while the electrode lead terminal 103a of the other piezoelectric ceramic stacked layer 103 is a negative electrode (or a positive electrode).

The two adjacent electrode lead terminals 103a among the two or more electrode lead terminals 103a are arranged in a staggered manner in the axial direction of the columnar piezoelectric ceramic body 10, and each of the electrode lead terminals 103a is exposed to an external environment. One of the electrode lead terminals 103a is disposed only on the surface of the corresponding one of the piezoelectric ceramic stacked layers 103, and is not in direct contact with the adjacent piezoelectric ceramic stacked layers 103. The two electrode lead terminals 103a are arranged in the staggered manner in the axial direction of the columnar piezoelectric ceramic body 10, such that the two adjacent electrode lead terminals 103a form a yielding space with each other without positional interference, thereby facilitating subsequently securing the connecting wires on the electrode lead terminals 103a.

When the two or more piezoelectric ceramic stacked layers 103 in the present embodiment are stacked in a predetermined stacking manner to form the columnar piezoelectric ceramic body 10, the two or more piezoelectric ceramic stacked layers 103 after the completion of the stacking operation are tightly connected by using the connecting component 20 according to the present embodiment, thereby avoiding separation of the two or more piezoelectric ceramic stacked layers 103 after the completion of the stacking operation.

In the piezoelectric ceramic stacked structure according to the present embodiment of the disclosure, each of the two or more piezoelectric ceramic stacked layers 103 is provided with one electrode lead terminal 103a, and the external device may be directly and electrically connected with the electrode lead terminal 103a. Therefore, there is no need to separately provide an electrode sheet between the two adjacent piezoelectric ceramic stacked layers 103. Consequently, the piezoelectric ceramic stacked structure is simple and compact, thereby improving the overall rigidity of the multilayer piezoelectric ceramic stacked structure and improving the frequency response characteristic.

The two adjacent piezoelectric ceramic stacked layers 103 according to the present embodiment of the disclosure are disposed in direct contact with each other. Of the two adjacent piezoelectric ceramic stacked layers 103, the end surface of one piezoelectric ceramic stacked layer 103 facing the second end portion 102 is in direct contact with the end surface of the other piezoelectric ceramic stacked layer 103 facing the first end portion 101, thereby improving the connection rigidity of the two adjacent piezoelectric ceramic stacked layers 103. The connection between the two or more piezoelectric ceramic stacked layers 103 enables the connecting component 20 to be locked. In this way, there is no need to provide connecting layer, adhesive or the like between the two adjacent piezoelectric ceramic stacked layers 103, so that the rigidity of the multilayer piezoelectric ceramic stacked structure can be further improved, and the problem of stress fluctuations when used in the high temperature environment can be also greatly reduced.

Each of the two or more piezoelectric ceramic stacked layers 103 according to the present embodiment of the disclosure is provided with an electrode lead terminal accommodating portion. The electrode lead terminal accommodating portions of the two adjacent piezoelectric ceramic stacked layers 103 are arranged in a staggered manner in the axial direction of the columnar piezoelectric ceramic body 10.

As shown in FIG. 3, the electrode lead terminal accommodating portion according to the present embodiment of the disclosure may be a through groove 104. The through groove 104 is disposed on the outer peripheral surface of each of the two or more piezoelectric ceramic stacked layers 103 and extends along the axial direction of the columnar piezoelectric ceramic body 10. The through groove 104 penetrates the first end portion 101 and the second end portion 102. From the first end portion 101 to the second end portion 102, one of all the through grooves 104 provided on each of the two or more piezoelectric ceramic stacked layers 103 and the electrode lead terminal 103a of the adjacent piezoelectric ceramic stacked layer 103 are disposed to be aligned with each other. The through groove 104 may form a yielding space such that the electrode lead terminals 103a disposed in alignment therewith are exposed to the external environment, facilitating subsequently securing the connecting wires on the electrode lead terminals 103a. The through groove 104 according to this embodiment is a straight groove. The number of the through grooves 104 may be one or two or more. Further, the number of the through grooves 104 provided on the outer peripheral surface of each of the two or more piezoelectric ceramic stacked layers 103 is less than the number of the piezoelectric ceramic stacked layers 103 included in the cylindrical piezoelectric ceramic body 10 by one. Thus, the two or more electrode lead terminals 103a can be disposed to be spirally staggered along the axial direction of the columnar piezoelectric ceramic body 10 such that the overall structure of the columnar piezoelectric ceramic body 10 is more reasonable and compact.

In one embodiment, the contour of the cross section of the through groove 104 according to the present embodiment has a polygon shape. In another embodiment, the contour at the bottom of the cross section of the through groove 104 according to the present embodiment has a circular arc shape, and the contour at the groove opening of the through groove 104 has a rounded shape. Thus, the portion of the piezoelectric ceramic stacked layer 103 corresponding to the through groove 104 is transitioned smoothly, avoiding the occurrence of a stress-concentrated pointed region, so that the piezoelectric ceramic stacked layer 103 has a good overall structural rigidity and is less likely to be cracked and broken.

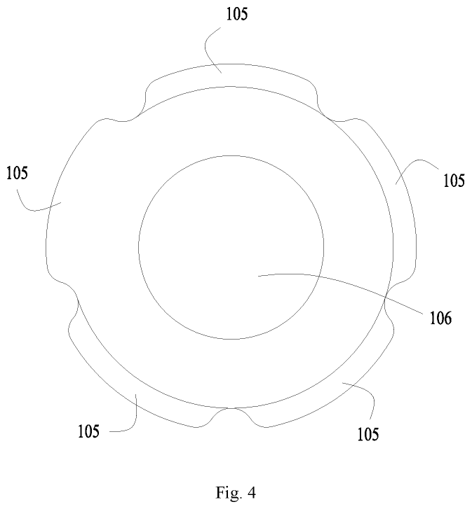

As shown in FIG. 4, the electrode lead terminal accommodating portion according to the present embodiment of the disclosure may also be a protruding portion 105 which is disposed on each of the two or more piezoelectric ceramic stacked layers 103. In the present embodiment, the protruding portion 105 extends along the radial direction of the columnar piezoelectric ceramic body 10. The electrode lead terminal 103a is disposed on a surface of the protruding portion 105 facing the first end portion 101. The protruding portions 105 respectively disposed on the two adjacent piezoelectric ceramic stacked layers 103 are disposed in a staggered manner along the axial direction of the columnar piezoelectric ceramic body 10, thereby forming a yielding space to avoid interference of the position. Each of the two or more piezoelectric ceramic stacked layers 103 according to the present embodiment is provided with one protruding portion 105. All of the protruding portions 105 included in the columnar piezoelectric ceramic body 10 may be disposed to be spirally staggered along the axial direction of the columnar piezoelectric ceramic body 10, thereby facilitating securing the connecting wires on the surface of the protruding portion 105 facing the first end portion 101.

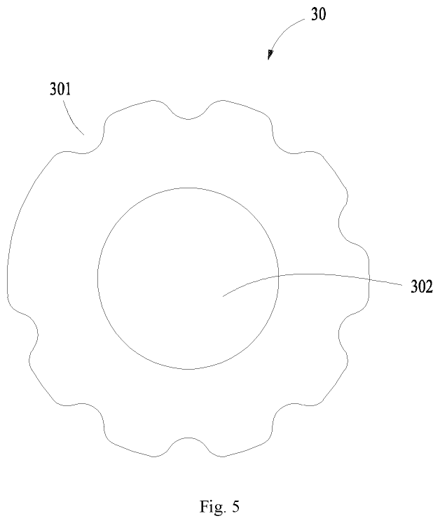

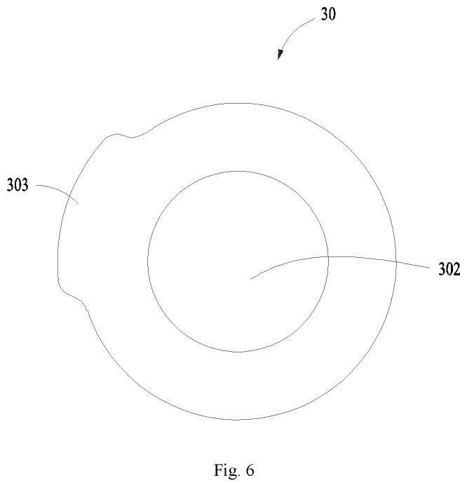

Each of the two or more piezoelectric ceramic stacked layers 103 according to the present embodiment of the disclosure includes one or two or more piezoelectric ceramic sheets 30 (as shown in FIG. 5 or FIG. 6). Each of the upper surface and the lower surface of the piezoelectric ceramic sheet 30 is provided with a conductive layer, for example, each of the upper surface and the lower surface is plated with gold to form the conductive layer. The piezoelectric ceramic sheet 30 includes a positive electrode and a negative electrode. The thickness of the piezoelectric ceramic sheet 30 may be processed as required. When each of the two or more piezoelectric ceramic stacked layers 103 includes two or more piezoelectric ceramic sheets 30, the two adjacent electrodes of the two adjacent piezoelectric ceramic sheets 30 have opposite polarities, that is, of two adjacent piezoelectric ceramic sheets, the two electrodes of one piezoelectric ceramic sheet 30 opposite to the other piezoelectric ceramic sheet 30 have opposite polarities, so that two or more piezoelectric ceramic sheets 30 are stacked in series to form one piezoelectric ceramic stacked layer 103.

In one embodiment, as shown in FIG. 5, the outer peripheral surface of the individual piezoelectric ceramic sheet 30 is provided with recesses 301. The recesses 301 provided respectively on all piezoelectric ceramic sheets 30 included in each piezoelectric ceramic stacked layer 103 form the through groove 104. The recess 301 on the piezoelectric ceramic sheet 30 according to the present embodiment may be manufactured by a laser cutting process, and may also be manufactured by a molding process.

In one embodiment, as shown in FIG. 6, the outer peripheral surface of the individual piezoelectric ceramic sheets 30 is provided with protrusions 303. The protrusions 303 provided respectively on all piezoelectric ceramic sheets 30 included in each piezoelectric ceramic stacked layer 103 form the protruding portion 105. The piezoelectric ceramic sheet 30 provided with the protrusions 303 in the present embodiment may be formed as a whole by a molding process. In the present embodiment, when one piezoelectric ceramic stacked layer 103 includes two or more piezoelectric ceramic sheets 30 and each of the two or more piezoelectric ceramic sheets 30 is provided with protrusions 303, the electrode lead terminal 103a is disposed on the surface of the protrusion 303 provided on the piezoelectric ceramic sheet 30 near the first end portion 101.

The two adjacent piezoelectric ceramic stacked layers 103 according to the present embodiment of the disclosure may respectively include same or different numbers of the piezoelectric ceramic sheets 30. In one embodiment, each of the two or more piezoelectric ceramic stacked layers 103 in the columnar piezoelectric ceramic body 10 includes one piezoelectric ceramic sheet 30. The electrodes of the two adjacent piezoelectric ceramic sheets 30 have the same polarity, so that the respective piezoelectric ceramic sheets 30 are stacked in parallel to form the columnar piezoelectric ceramic body 10. The protrusions 303 provided on all of the piezoelectric ceramic sheets 30 may be disposed to be spirally staggered along the axial direction of the cylindrical piezoelectric ceramic body 10, thereby facilitating securing the connecting wires on the surface of the protruding portions 303 facing the first end portion 101. In one embodiment, the two adjacent piezoelectric ceramic stacked layers 103 includes respectively different numbers of the piezoelectric ceramic sheets 30. For example, one of the two adjacent piezoelectric ceramic stacked layers 103 includes three piezoelectric ceramic sheets 30, while the other of the two adjacent piezoelectric ceramic stacked layer 103 includes one piezoelectric ceramic sheet 30. Thus, the number of piezoelectric ceramic sheets 30 included in each piezoelectric ceramic stacked layer 103 may be freely configured as required.

Since the respective piezoelectric ceramic stacked layers 103 according to the present embodiment of the disclosure are connected in direct contact, the piezoelectric ceramic stacked structure according to the present embodiment of the disclosure further includes the connecting component 20 for fixing the respective piezoelectric ceramic stacked layers 103. The connecting component 20 according to the present embodiment of the disclosure includes a first pressing portion and a second pressing portion. The first pressing portion and the second pressing portion are respectively used to apply a pressing force to the end surface of the first end portion 101 and the end surface of the second end portion 102, thereby locking the respective piezoelectric ceramic stacked layers 103 and preventing the respective piezoelectric ceramic stacked layers 103 from being loosely separated. In the present embodiment, the direction of the pressing force is along the axial direction of the columnar piezoelectric ceramic body 10.

A first insulating member 40 is provided between the first pressing portion of the connecting component 20 according to the present embodiment of the disclosure and the piezoelectric ceramic stacked layer 103 disposed at the first end portion 101 of the columnar piezoelectric ceramic body 10 to maintain an insulating state between the first pressing portion of the connecting component 20 and the electrode of the piezoelectric ceramic stacked layer 103. In one embodiment, the first insulating member 40 has a sheet-like structure. The outer peripheral surface of the first insulating member 40 of the sheet-like structure may be provided with a recess having the same cross-sectional shape as that of the through groove 104. The material of the first insulating member 40 according to the present embodiment is alumina ceramic, mica or the like.

As shown in FIG. 1 and FIG. 2, a positive electrode sheet 50 and a negative electrode sheet 70 are provided between the second pressing portion of the connecting component 20 according to the present embodiment of the disclosure and the piezoelectric ceramic stacked layer 103 disposed at the second end portion 102 of the columnar piezoelectric ceramic body 10. The positive electrode sheet 50 and the negative electrode sheet 70 according to the present embodiment are stacked in the axial direction of the columnar piezoelectric ceramic body 10. Each of the electrode lead terminals 103a is electrically connected with the positive electrode sheet 50 or the negative electrode sheet 70, respectively. The electrode lead terminal 103a of the positive electrode disposed on the piezoelectric ceramic stacked layer 103 is electrically connected with the positive electrode sheet 50 through wires. The electrode lead terminal 103a of the negative electrode disposed on the piezoelectric ceramic stacked layer 103 is electrically connected with the negative electrode sheet 70 through wires. Thus, it is convenient to collect the electrode lead terminals 103a of all the positive electrodes and the electrode lead terminals 103a of the negative electrode together through the positive electrode sheet 50 and the negative electrode sheet 70, thereby avoiding overlapping or winding of the wires drawn from the respective electrode lead terminals 103a. The wires according to this embodiment may be gold wires.

A second insulating member 60 is provided between the positive electrode sheet 50 and the negative electrode sheet 70 according to the present embodiment to maintain an insulating state between the positive electrode sheet 50 and the negative electrode sheet 70. A third insulating member 80 is provided between the positive electrode sheet 50 or the negative electrode sheet 70 and the second pressing portion to maintain an insulating state between the positive electrode sheet 50 or the negative electrode sheet 70 and the second pressing portion. The material of the second insulating member 60 and the third insulating member 80 according to the present embodiment is alumina ceramic, mica or the like. The positive electrode sheet 50, the second insulating member 60, the negative electrode sheet 70, and the third insulating member 80 according to the present embodiment are respectively stacked along the axial direction of the columnar piezoelectric ceramic body 10.

The position of both the positive electrode sheet 50 and the negative electrode sheet 70 are determined by the polarity of the electrode of the piezoelectric ceramic stacked layer 103 disposed at the second end portion 102 of the columnar piezoelectric ceramic body 10. When the electrode of the piezoelectric ceramic stacked layer 103 disposed at the second end portion 102 of the columnar piezoelectric ceramic body 10 is a positive electrode, the positive electrode sheet 50 is directly and electrically connected to the piezoelectric ceramic stacked layer 103 of the second end portion 102. When the electrode of the piezoelectric ceramic stacked layer 103 disposed at the second end portion 102 of the columnar piezoelectric ceramic body 10 is a negative electrode, the negative electrode sheet 70 is directly and electrically connected to the piezoelectric ceramic stacked layer 103 of the second end portion 102.

In the present embodiment of the disclosure, the first pressing portion is the head 201 of the bolt and the second pressing portion is the nut 202 of the bolt, so that the structure of the connecting component 20 is simple and the connection state is stable. As shown in FIG. 3, each of the two or more piezoelectric ceramic stacked layers 103 includes a central through hole 106. In one embodiment, a central hole 302 is formed in each of the two or more piezoelectric ceramic sheets 30 by a laser cutting process. The respective piezoelectric ceramic sheets 30 are coaxially stacked, and the central holes 302 of the respective piezoelectric ceramic sheets 30 form the central through hole 106. Each of the two or more piezoelectric ceramic stacked layers 103 is sleeved on the stud of the bolt 201. The hole wall of the center through hole 106 of each piezoelectric ceramic stacked layer 103 is disposed to be insulated from or be in clearance fit with the outer peripheral surface of the stud. In one embodiment, a rigid insulating member may be provided between the stud and the hole wall to effect an insulation fit therebetween. In one embodiment, the diameter of the stud is smaller than the diameter of the central through hole 106 such that a clearance is formed between the hole wall of the center through hole 106 of the piezoelectric ceramic stacked layer 103 and the outer peripheral surface of the stud.

In one embodiment, the first insulating member 40, the positive electrode sheet 50, the second insulating member 60, the negative electrode sheet 70, and the third insulating member 80 are all annular structural bodies. When the piezoelectric ceramic stacked structure according to the present embodiment of the disclosure is assembled, the third insulating member 80, the positive electrode sheet 50 (or the negative electrode sheet 70), the second insulating member 60, the negative electrode sheet 70 (or the positive electrode sheet 50), each of the two or more piezoelectric ceramic stacked layers 103, and the first insulating member 40 are sequentially sleeved on the stud of the bolt 201, and the nut 202 is then screwed on the stud until the respective structural members are locked by the nut 202 in the axial direction of the columnar piezoelectric ceramic body 10. Thus, the assembly operation of the piezoelectric ceramic stacked structure is completed.

The piezoelectric ceramic stacked structure according to the present embodiment of the disclosure has a simple overall structure and is suitable for mass production. Each of the two or more piezoelectric ceramic stacked layers 103 in the piezoelectric ceramic stacked structure is provided with one electrode lead terminal 103a. Since the electrode lead terminal 103a is exposed to the external environment, the external device can be directly and electrically connected with the electrode lead terminal 103a, thereby solving the problem that the leads cannot be drawn out when the two adjacent piezoelectric ceramic stacked layers 103 are directly in contact with each other. In this way, there is no need to separately provide the electrode sheets on the two adjacent piezoelectric ceramic stacked layers 103. The piezoelectric ceramic stacked structure is formed by directly stacking, thereby improving the rigidity of the piezoelectric ceramic stacked structure as a whole and improving the frequency response characteristics. In addition, the connection between the two or more piezoelectric ceramic stacked layers 103 enables the connecting component 20 to be locked. There is no need to provide a connecting layer or an adhesive between the two adjacent piezoelectric ceramic stacked layers 103, so that the rigidity of the multilayer piezoelectric ceramic stacked structure can be further improved. The columnar piezoelectric ceramic body 10 is formed by stacking the piezoelectric ceramic stacked layers 103 having the same expansion coefficient, thereby reducing the influence of stress fluctuations when used in the high temperature environment, and improving the frequency response characteristics in the high temperature environment.

The embodiment of the disclosure also includes a piezoelectric accelerometer including the piezoelectric ceramic stacked structure according to the above embodiment. In the normal temperature state, the piezoelectric accelerometer according to the present embodiment has good frequency response characteristics. In the high temperature environment, the piezoelectric accelerometer according to the present embodiment is less affected by the stress value fluctuations generated when the piezoelectric ceramic stacked structure is subjected to thermal to be expanded, and has good high frequency response characteristic. Thus, the piezoelectric accelerometer according to the present embodiment has high detection accuracy.

Although the disclosure has been described with reference to the preferred embodiments, various modifications may be made thereto and the components may be replaced with equivalents without departing from the scope of the application. In particular, the technical features mentioned in the various embodiments can be combined in any manner as long as there is no structural conflict. The disclosure is not limited to the specific embodiments disclosed herein, but includes all technical solutions falling within the scope of the claims.

1. A piezoelectric ceramic stacked structure, comprising:
a columnar piezoelectric ceramic body, comprising a first end portion and a second end portion opposite to each other in an axial direction thereof, wherein the columnar piezoelectric ceramic body comprises two or more piezoelectric ceramic stacked layers, and two adjacent electrodes of two adjacent piezoelectric ceramic stacked layers among the two or more piezoelectric ceramic stacked layers have the same polarity,
a surface, facing the first end portion, of each of the two or more piezoelectric ceramic stacked layers is provided with an electrode lead terminal, and
two adjacent electrode lead terminals among the two or more piezoelectric ceramic stacked layers have opposite polarities and are arranged in a staggered manner in the axial direction, and the electrode lead terminal provided on each of the two or more piezoelectric ceramic stacked layers in the columnar piezoelectric ceramic body is exposed to an external environment; and
a connecting component, wherein the two or more piezoelectric ceramic stacked layers are connected by the connecting component.

2. The piezoelectric ceramic stacked structure according to claim 1, wherein the two adjacent piezoelectric ceramic stacked layers are disposed in direct contact.

3. The piezoelectric ceramic stacked structure according to claim 1, wherein each of the two or more piezoelectric ceramic stacked layers is provided with an electrode lead terminal accommodating portion, electrode lead terminal accommodating portions of the two adjacent piezoelectric ceramic stacked layers are arranged in a staggered manner in the axial direction.

4. The piezoelectric ceramic stacked structure according to claim 3, wherein the electrode lead terminal accommodating portion is a through groove which is provided on an outer peripheral surface of each of the two or more piezoelectric ceramic stacked layers and extends along the axial direction, from the first end portion to the second end portion, one of the through grooves provided on each of the two or more piezoelectric ceramic stacked layers and the electrode lead terminal of the adjacent piezoelectric ceramic stacked layer are disposed in alignment with each other.

5. The piezoelectric ceramic stacked structure according to claim 4, wherein the number of the through grooves provided on each of the two or more piezoelectric ceramic stacked layers is less than the number of the piezoelectric ceramic stacked layers comprised in the columnar piezoelectric ceramic body by one.

6. The piezoelectric ceramic stacked structure according to claim 4, wherein a contour at bottom of a cross section of the through groove has a circular arc shape, and a contour at a groove opening of the through groove has a rounded shape; or a contour of the cross section of the groove has a polygon shape.

7. The piezoelectric ceramic stacked structure according to claim 3, wherein the electrode lead terminal accommodating portion is a protruding portion which is provided on each of the two or more piezoelectric ceramic stacked layers and extends along a radial direction of the columnar piezoelectric ceramic body, and the electrode lead terminal is disposed on a surface of the protruding portion facing the first end portion.

8. The piezoelectric ceramic stacked structure according to claim 1, wherein each of the two or more piezoelectric ceramic stacked layers comprises one or two or more piezoelectric ceramic sheets, the two adjacent piezoelectric ceramic stacked layers comprises respectively the same or different numbers of the piezoelectric ceramic sheets, and two adjacent electrodes of the two adjacent piezoelectric ceramic sheets have opposite polarities when each of the two or more piezoelectric ceramic stacked layers comprises the two or more the piezoelectric ceramic sheets.

9. The piezoelectric ceramic stacked structure according to claim 1, wherein the connecting component comprises a first pressing portion and a second pressing portion, the first pressing portion and the second pressing portion are respectively configured to apply a pressing force to an end surface of the first end portion and an end surface of the second end portion.

10. The piezoelectric ceramic stacked structure according to claim 9, further comprising: a first insulating member disposed between the piezoelectric ceramic stacked layer located at the first end portion and the first pressing portion.

11. The piezoelectric ceramic stacked structure according to claim 9, further comprising: a positive electrode sheet and a negative electrode sheet disposed between the piezoelectric ceramic stacked layer located at the second end portion and the second pressing portion, wherein the electrode lead terminal of each of the two or more piezoelectric ceramic stacked layers is electrically connected to the positive electrode sheet or the negative electrode sheet, and a second insulating member is disposed between the positive electrode sheet and the negative electrode sheet, and a third insulating member is disposed between the positive electrode sheet or the negative electrode sheet and the second pressing portion.

12. The piezoelectric ceramic stacked structure according to claim 9, wherein the first pressing portion is a head of a bolt, the second pressing portion is a nut of the bolt, each of the two or more piezoelectric ceramic stacked layers comprises a central through hole, each of the two or more piezoelectric ceramic stacked layers is sleeved on a stud of the bolt, and a hole wall of the center through hole is disposed to be insulated from or be in clearance fit with the stud.

13. A piezoelectric accelerometer comprising:
a piezoelectric ceramic stacked structure comprising:
a columnar piezoelectric ceramic body, comprising a first end portion and a second end portion opposite to each other in an axial direction thereof, wherein the columnar piezoelectric ceramic body comprises two or more piezoelectric ceramic stacked layers, and two adjacent electrodes of two adjacent piezoelectric ceramic stacked layers among the two or more piezoelectric ceramic stacked layers have the same polarity,
a surface, facing the first end portion, of each of the two or more piezoelectric ceramic stacked layers is provided with an electrode lead terminal, and
two adjacent electrode lead terminals among the two or more piezoelectric ceramic stacked layers have opposite polarities and are arranged in a staggered manner in the axial direction, and the electrode lead terminal provided on each of the two or more piezoelectric ceramic stacked layers in the columnar piezoelectric ceramic body is exposed to an external environment; and
a connecting component, wherein the two or more piezoelectric ceramic stacked layers are connected by the connecting component.

14. The piezoelectric accelerometer according to claim 13, wherein the two adjacent piezoelectric ceramic stacked layers are disposed in direct contact.

15. The piezoelectric accelerometer according to claim 13, wherein each of the two or more piezoelectric ceramic stacked layers is provided with an electrode lead terminal accommodating portion, electrode lead terminal accommodating portions of the two adjacent piezoelectric ceramic stacked layers are arranged in a staggered manner in the axial direction.

16. The piezoelectric accelerometer according to claim 15, wherein the electrode lead terminal accommodating portion is a through groove which is provided on an outer peripheral surface of each of the two or more piezoelectric ceramic stacked layers and extends along the axial direction, from the first end portion to the second end portion, one of the through grooves provided on each of the two or more piezoelectric ceramic stacked layers and the electrode lead terminal of the adjacent piezoelectric ceramic stacked layer are disposed in alignment with each other.

17. The piezoelectric accelerometer according to claim 16, wherein the number of the through grooves provided on each of the two or more piezoelectric ceramic stacked layers is less than the number of the piezoelectric ceramic stacked layers comprised in the columnar piezoelectric ceramic body by one.

18. The piezoelectric accelerometer according to claim 16, wherein a contour at bottom of a cross section of the through groove has a circular arc shape, and a contour at a groove opening of the through groove has a rounded shape; or a contour of the cross section of the groove has a polygon shape.

19. The piezoelectric accelerometer according to claim 15, wherein the electrode lead terminal accommodating portion is a protruding portion which is provided on each of the two or more piezoelectric ceramic stacked layers and extends along a radial direction of the columnar piezoelectric ceramic body, and the electrode lead terminal is disposed on a surface of the protruding portion facing the first end portion.

20. The piezoelectric accelerometer according to claim 15, wherein each of the two or more piezoelectric ceramic stacked layers comprises one or two or more piezoelectric ceramic sheets, the two adjacent piezoelectric ceramic stacked layers comprises respectively the same or different numbers of the piezoelectric ceramic sheets, and two adjacent electrodes of the two adjacent piezoelectric ceramic sheets have opposite polarities when each of the two or more piezoelectric ceramic stacked layers comprises the two or more the piezoelectric ceramic sheets.
